(19) United States
(12) Patent Application Publication
(10) Pub. No.: US 2026/0147170 A1
(43) Pub. Date: May 28, 2026

(54) CO-PACKAGED OPTICAL MODULES

(71) Applicant: International Business Machines Corporation, Armonk, NY (US)

(72) Inventors: John Knickerbocker, Monroe, NY (US); Akihiro Horibe, Yokohama (JP); Hsianghan Hsu, Latham, NY (US); Neng Liu, Albany, NY (US); Adrian Paz Ramos, Montreal (CA); Jean Benoit Heroux, Brossard (CA); Qianwen Chen, Chappaqua, NY (US); Sayuri Hada, Tokyo (JP); CHINAMI ISHIKAWA, Yokohama-city (JP); Yoichi Taira, Tokyo (JP)

(21) Appl. No.: 18/963,715

(22) Filed: Nov. 28, 2024

(51) Int. Cl. G02B 6/42; H01L 23/00; H01L 25/16

(52) U.S. Cl. CPC G02B 6/4239; G02B 6/4242; H10W 42/121; H10W 90/00

(57) ABSTRACT

Co-packaged optical modules having high bandwidth density, low insertion loss, and solder reflow and reliability stress compatibility are provided. In one aspect, an optical module includes: a photonic integrated circuit attached to a substrate; a lid in direct contact with the substrate such that the photonic integrated circuit is present in between the substrate and the lid; optical waveguides attached to the photonic integrated circuit; and a ferrule attached to the optical waveguides. The lid can be present over the photonic integrated circuit, and directly contacts a top of the substrate. Conversely, the lid can be present below the photonic integrated circuit, and directly contacts a bottom of the substrate.

### BACKGROUND

The present invention generally relates to photonics, and, more particularly, to co-packaged optical modules having high bandwidth density, low insertion loss, and solder reflow and reliability stress compatibility.

Photonic integrated circuits or PICs are used in a variety of different applications from fiber optic-based communication to quantum computing. As compared to electronic integrated circuits which employ electrons, photonic integrated circuits use photons (which are particles of light) to process information. As its name implies, a photonic integrated circuit contains photonic components that work together as a functioning circuit.

Optical waveguides are an important building block of photonic integrated circuit designs, as they provide a means for transmitting data. Namely, optical waveguides typically include a core material surrounded by a cladding material that operate in concert to transmit electromagnetic waves in the optical spectrum with a target of low insertion loss for intended wavelength(s) of use.

### BRIEF SUMMARY

Principles of the invention provide co-packaged optical modules having high bandwidth density, low insertion loss, and solder reflow and reliability stress compatibility. In one aspect, an optical module is provided. The optical module includes: a photonic integrated circuit attached to a substrate; a lid in direct contact with the substrate such that the photonic integrated circuit is present in between the substrate and the lid; optical waveguides attached to the photonic integrated circuit; and a ferrule attached to the optical waveguides.

The optical waveguides can have a fan-out pattern. For instance, the optical waveguides can fan out from a first pitch P1 at the photonic integrated circuit to a second pitch P2 at the ferrule, where P1<P2. Also, the ferrule attached to the optical waveguides can be a first ferrule, and the optical module can further include: a second ferrule attached to a single mode fiber array. The second ferrule is coupled to the first ferrule.

The optical waveguides can be attached to the photonic integrated circuit using a first adhesive. A second adhesive can be disposed on one or more edges of the optical waveguides at a junction of the optical waveguides to the photonic integrated circuit and/or at a junction of the optical waveguides to the ferrule. At least one of the first adhesive and the second adhesive can be an epoxy-based adhesive. Further, at least one of the first adhesive and the second adhesive can be a polyimide-based adhesive.

In another aspect, another optical module is provided. The optical module includes: a photonic integrated circuit attached to a substrate; a lid over the photonic integrated circuit, where the lid directly contacts a top of the substrate such that the photonic integrated circuit is present in between the substrate and the lid; optical waveguides attached to the photonic integrated circuit; and a ferrule attached to the optical waveguides. A socket can be attached to the lid above the photonic integrated circuit. The ferrule is plugged into the socket.

In yet another aspect, yet another optical module is provided. The optical module includes: a lid; a photonic integrated circuit disposed on the lid; a substrate over and attached to the photonic integrated circuit, where the lid directly contacts a bottom of the substrate such that the photonic integrated circuit is present in between the substrate and the lid; optical waveguides attached to the photonic integrated circuit; and a ferrule attached to the optical waveguides. A cut-out can be present in the substrate over the photonic integrated circuit. The cut-out provides access to the photonic integrated circuit by the optical waveguides.

As used herein, “facilitating” an action includes performing the action, making the action easier, helping to carry the action out, or causing the action to be performed. Thus, by way of example and not limitation, instructions executing on a processor might facilitate an action carried out by semiconductor fabrication equipment, by sending appropriate data or commands to cause or aid the action to be performed. Where an actor facilitates an action other than by performing the action, the action is nevertheless performed by some entity or combination of entities.

Techniques as disclosed herein can provide substantial beneficial technical effects, as will be discussed further below. Features and advantages will become apparent from the following detailed description of illustrative embodiments thereof, which is to be read in connection with the accompanying drawings.

### BRIEF DESCRIPTION OF THE DRAWINGS

The following drawings are presented by way of example only and without limitation, wherein like reference numerals (when used) indicate corresponding elements throughout the several views, and wherein:

FIG. 1 is a cross-sectional diagram depicting an exemplary optical module according to aspects of the invention;

FIG. 2 is a diagram illustrating an exemplary methodology for forming the optical module of FIG. 1 according to aspects of the invention;

FIGS. 3-5 are top-down diagrams illustrating the optical module of FIG. 1 co-packaged with a single mode fiber array through pluggable ferrules according to aspects of the invention;

FIG. 6 and FIG. 7 are diagrams illustrating a photonic integrated circuit and substrate of the optical module of FIG. 1 according to aspects of the invention;

FIG. 8 and FIG. 9 are three-dimensional depictions of the optical module of FIG. 1 according to aspects of the invention;

FIG. 10 is a cross-sectional diagram depicting another exemplary optical module according to aspects of the invention;

FIG. 11 is a diagram illustrating an exemplary methodology for forming the optical module of FIG. 10 according to aspects of the invention;

FIGS. 12-14 are top-down diagrams illustrating the optical module of FIG. 10 co-packaged with a single mode fiber array through pluggable ferrules according to aspects of the invention;

FIG. 15 and FIG. 16 are diagrams illustrating a photonic integrated circuit and substrate of the optical module of FIG. 10 according to aspects of the invention;

FIG. 17 and FIG. 18 are three-dimensional depictions of the optical module of FIG. 10 according to aspects of the invention;

FIG. 19A and FIG. 19B are schematic diagrams illustrating exemplary epoxy-based adiabatic coupling adhesives according to aspects of the invention;

FIGS. 20-23 are diagrams illustrating strength enhancements for the present optical waveguides according to aspects of the invention; and

FIGS. 24-26 are cross-sectional diagrams illustrating exemplary methodologies for implementing reworkable optical connections between the photonic integrated circuit and the optical waveguides according to aspects of the invention.

It is to be appreciated that elements in the figures are illustrated for simplicity and clarity. Common but well-understood elements that may be useful or necessary in a commercially feasible embodiment may not be shown in order to facilitate a less hindered view of the illustrated embodiments.

### DETAILED DESCRIPTION

Principles of inventions described herein will be in the context of illustrative embodiments. Moreover, it will become apparent to those skilled in the art given the teachings herein that numerous modifications can be made to the embodiments shown that are within the scope of the claims. That is, no limitations with respect to the embodiments shown and described herein are intended or should be inferred.

Given the discussion herein (reference characters refer to the drawings discussed below), it will be appreciated that in one aspect, an exemplary optical module (e.g., optical module 1000, optical module 10000, etc.) is provided. The optical module includes: a photonic integrated circuit (e.g., photonic integrated circuit 1010, photonic integrated circuit 10010, etc.) attached to a substrate (e.g., substrate 1006, substrate 10006, etc.); a lid (e.g., lid 1012, lid 10012, etc.) in direct contact with the substrate such that the photonic integrated circuit is in between the substrate and the lid; optical waveguides (e.g., optical waveguides 1014, optical waveguides 10014, etc.), attached to the photonic integrated circuit; and a ferrule (e.g., ferrule 1030, ferrule 10030, etc.) attached to the optical waveguides.

The optical waveguides (e.g., optical waveguides 1014, optical waveguides 10014, etc.) can have a fan-out pattern. For instance, the optical waveguides can fan out from a first pitch P1 (or P1′) at the photonic integrated circuit (e.g., photonic integrated circuit 1010, photonic integrated circuit 10010, etc.) to a second pitch P2 (or P2′) at the ferrule (e.g., ferrule 1030, ferrule 10030, etc.), where P1<P2 (or P1′<P2′). Also, the ferrule attached to the optical waveguides (e.g., optical waveguides 1014, optical waveguides 10014, etc.) can be a first ferrule, and the optical module (e.g., optical module 1000, optical module 10000, etc.) can further include: a second ferrule (e.g., ferrule 3004, ferrule 12004, etc.) attached to a single mode fiber array (e.g., single mode fiber array 3002, single mode fiber array 12002, etc.). The second ferrule is coupled to the first ferrule.

The optical waveguides (e.g., optical waveguides 1014, optical waveguides 10014, etc.) can be attached to the photonic integrated circuit (e.g., photonic integrated circuit 1010, photonic integrated circuit 10010, etc.) using a first adhesive. A second adhesive can be disposed on one or more edges of the optical waveguides at a junction of the optical waveguides to the photonic integrated circuit and/or at a junction of the optical waveguides to the ferrule (e.g., ferrule 1030, ferrule 10030, etc.). At least one of the first adhesive and the second adhesive (e.g., adiabatic coupling adhesive 4002, adiabatic coupling adhesive 13002, etc. and/or e.g., mechanical adhesive 5002, mechanical adhesive 14002, etc.) can be an epoxy-based adhesive. Further, at least one of the first adhesive and the second adhesive can be a polyimide-based adhesive.

In another aspect, another optical module (e.g., optical module 1000) is provided. The optical module includes: a photonic integrated circuit (e.g., photonic integrated circuit 1010) attached to a substrate (e.g., substrate 1006); a lid (e.g., lid 1012) over the photonic integrated circuit, where the lid directly contacts a top of the substrate such that the photonic integrated circuit is in between the substrate and the lid; optical waveguides (e.g., optical waveguides 1014) attached to the photonic integrated circuit; and a ferrule (e.g., ferrule 1030) attached to the optical waveguides. A socket (e.g., socket 1032) can be attached to the lid above the photonic integrated circuit. The ferrule is plugged into the socket.

In yet another aspect, yet another optical module (e.g., optical module 10000) is provided. The optical module includes: a lid (e.g., lid 10012); a photonic integrated circuit (e.g., photonic integrated circuit 10010) disposed on the lid; a substrate (e.g., substrate 10006) over and attached to the photonic integrated circuit, where the lid directly contacts a bottom of the substrate such that the photonic integrated circuit is in between the substrate and the lid; optical waveguides (e.g., optical waveguides 10014) attached to the photonic integrated circuit; and a ferrule (e.g., ferrule 10030) attached to the optical waveguides. A cut-out (e.g., cut-out 10042) can be present in the substrate over the photonic integrated circuit. The cut-out provides access to the photonic integrated circuit by the optical waveguides.

Techniques as disclosed herein can provide substantial beneficial technical effects. Some embodiments may not have these potential advantages and these potential advantages are not necessarily required of all embodiments. By way of example only and without limitation, one or more embodiments of the present co-packaged optical modules can provide one or more of:
High bandwidth density photonic integrated circuit to optical waveguide designs and fan-out to a single mode fiber array via pluggable ferrule with enhanced reflow and stress compatibility;
Co-packaged optic module structures obtained using photonic integrated circuit first and last integration methods based on lid-to-substrate and lid-to-ferrule configurations;
Use of adiabatic coupling adhesives for optical and mechanical attachment that are reflow compatible and support minimal, if any, insertion loss change; and
Improved durability and strength obtained through use of optional mechanical and/or scaling adhesives and/or coatings.

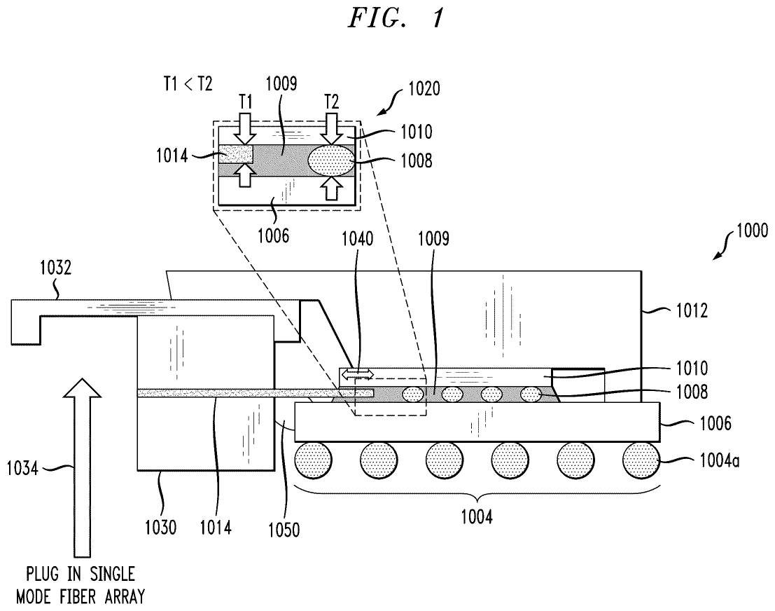

For instance, referring to FIG. 1, an optical module 1000 in accordance with the present techniques is shown. As will be described in detail below, the present optical module designs such as the optical module 1000 shown in FIG. 1 capture a high bandwidth and density of a photonic integrated circuit or PIC to an optical waveguide and achieve a very good effective pitch on the photonic integrated circuit through edge connections.

The term ‘effective pitch’ as used herein generally refers to the spacing, center-to-center, of adjacent leads or pins on an integrated circuit relative to the overall component width. For instance, by way of example only, the present optical module designs enable a physical pitch of from about 18 micrometers (μm) to about 250 μm or more from the center of one optical waveguide to the center of an adjacent optical waveguide. For example, for an 18 μm pitch from the center of one waveguide to the center of another waveguide, an effective pitch on the photonic integrated circuit (PIC) circuit would include the 18 μm pitch times the number of waveguides plus some added width before the first waveguide and after the last waveguide for processing, structural integrity and integration and/or could include one or more waveguides on each side for spares or for other structural or process benefit. For instance, if an optical waveguide had 24 channels at an 18 μm pitch, then the physical width of the waveguide would be approximately 432 μm prior to addition of buffer. With buffer as by way of example, the effective pitch became 432 μm plus this example buffer of 36 μm on each side of the optical waveguides for PIC to polymer optical waveguide total width of 504 μm and when divided by the 24 waveguide channels provides a PIC to polymer optical waveguide average effective pitch of 21 μm/waveguide rather than the physical wide of the 24 waveguide channels of about 18 μm. As the name implies, ‘edge connections’ are those connections that are present at one or more edges of the optical module, at one or more edges of the photonic integrated circuit, and/or at one or more edges of any of their constituent components.

As will also be described in detail below, the present optical module can include a fan-out to a single mode fiber or SMF array with a pluggable ferrule, and can also include microelectronics which is referred to herein as a co-packaged optic, meaning that the components of the optical module and microelectronics are co-designed to be compatible with one another, can support optical and electrical component assemblies and reliability stress testing, and that both electrical and optical links are provided on the co-packaged optical module.

A pluggable ferrule or connector is generally any type of structure used for joining or fastening objects. In the context of the present techniques, ferrules will be employed to optically, electrically, etc. join objects such as optical waveguides. For instance, as will be described in detail below, a ferrule on the photonic integrated circuit optical waveguides and a corresponding ferrule on the single mode fiber array can be connected together to physically/optically join these components. Further, as will be described in detail below, the present design can be configured such that the ferrule on the single mode fiber array can simply be ‘plugged in’ to the optical module to achieve proper alignment of the single mode fiber array and the photonic integrated circuit optical waveguides.

Namely, as shown in FIG. 1, the optical module 1000 includes a substrate 1006 having a ball grid array or BGA 1004 on a bottom thereof, a photonic integrated circuit 1010 attached to a top of the substrate 1006 via solder bumps 1008 on a bottom of the photonic integrated circuit 1010, and a lid 1012 over the photonic integrated circuit 1010 and in direct contact with both a top of the photonic integrated circuit 1010 and a top of the substrate 1006 such that the photonic integrated circuit 1010 is present in between the substrate 1006 and the lid 1012. Substrate 1006 can generally be any type of material commonly used for a printed circuit board core such as a dielectric material. As is known to those of skill in the art, a ball grid array is simply a surface-mount packaging technique that employs an array of solder balls (e.g., solder balls 1004a) on the underside of a substrate (e.g., substrate 1006) that serve as electrical connections. According to an exemplary embodiment, the photonic integrated circuit 1010 is attached to the top of the substrate 1006 using the solder bumps 1008 via a flip chip process also known as controlled collapse chip connection or C4. The solder bumps 1008 are then encapsulated in an underfill material 1009 such as an electrically-insulating adhesive for enhanced bonding strength, enhanced reliability stress compatibility and performance. The lid 1012 can be formed of any suitable material that provides the structural integrity needed to hold the optical module 1000 together including, but not limited to, metals such as steel, aluminum and/or copper.

As shown in FIG. 1, optical waveguides 1014 (one of which is shown in cross-section) are attached to the photonic integrated circuit 1010. Hence, optical waveguides 1014 may also be referred to herein as ‘photonic integrated circuit optical waveguides.’ Suitable optical waveguides 1014 include, but are not limited to, polymer optical waveguides, glass optical waveguides, silicon (Si) optical waveguides, e.g., optical waveguides known in the art containing Si with silicon oxide (SiO₂) cladding and/or silicon nitride (SiN) with SiO₂ cladding, and/or alternate material waveguides such as, but not limited to, barium titanate (BaTiO₃) and/or lithium niobate (LiNbO₃) optical waveguides. Notably, according to an exemplary embodiment, the optical waveguides 1014 are thinner than the (C4 connection) solder bumps 1008 between the substrate 1006 and the photonic integrated circuit 1010. Namely, referring to magnified view 1020, the optical waveguides 1014 have a thickness T1 and the solder bumps 1008 have a thickness T2, where T1 is less than (<) T2. That way, the optical waveguides 1014 do not contact the substrate 1006 (i.e., the optical waveguides 1014 are in a non-contact position relative to the substrate 1006), thus avoiding the risk of compressing or pinching the optical waveguides 1014 during assembly.

As shown in FIG. 1, one (first) end of the optical waveguides 1014 is attached to the photonic integrated circuit 1010 and another (second) end of the optical waveguides 1014 is attached to a ferrule 1030 at an edge of the optical module 1000. An adhesive 1050 may be employed between the substrate 1006 and the ferrule 1030 for enhanced mechanical structure and/or optical enhancement. The adhesive 1050 can be any of the epoxy-based and/or polyimide-based adhesives described below. As highlighted above, ferrule 1030 will serve as a means for connecting (i.e., physically/optically joining) the optical waveguides 1014 to a single mode fiber array (see FIG. 3, below). Advantageously, a socket 1032 is also attached to the lid 1012 above the photonic integrated circuit 1010 into which the ferrule 1030 is plugged. Namely, as indicated by arrow 1034, when a corresponding ferrule attached to the single mode fiber array is also plugged into the socket 1032, it will align with ferrule 1030 thereby joining the optical waveguides 1014 to the single mode fiber array.

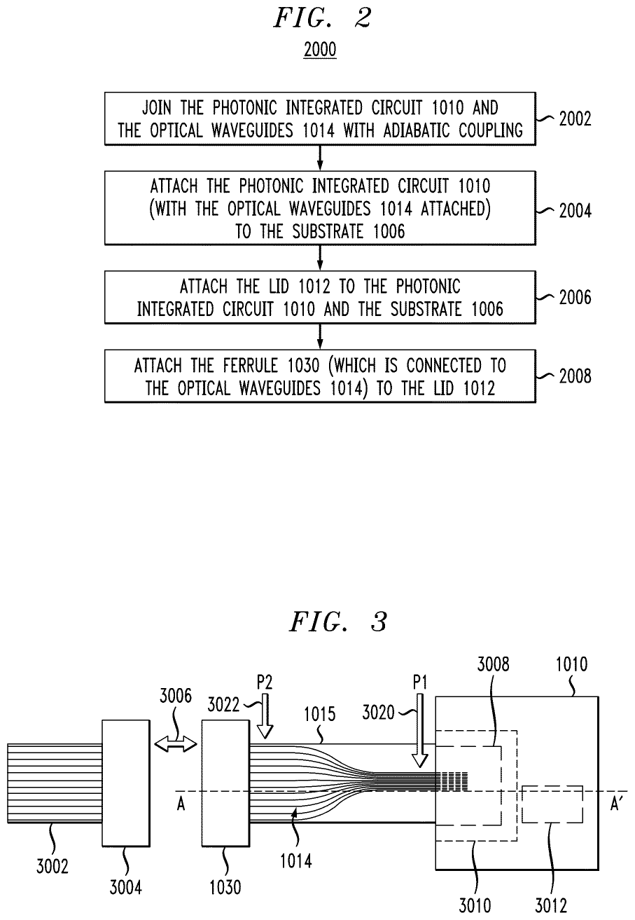

According to one exemplary embodiment, the optical module 1000 is formed via a photonic integrated circuit-first process, whereby the photonic integrated circuit 1010 and the optical waveguides 1014 are joined first, followed by all of the subsequent assembly processes for completing the optical module 1000, such as assembly of the lid 1012, ferrule 1030, etc. Sec, for instance, exemplary methodology 2000 in FIG. 2.

Namely, in step 2002, the photonic integrated circuit 1010 and the optical waveguides 1014 are joined with adiabatic coupling. By ‘adiabatic coupling’ it is meant here that the modes propagated through the photonic integrated circuit 1010 and the optical waveguides 1014 are essentially unchanged by the transition from one to another. According to an exemplary embodiment, such adiabatic coupling is achieved through the use of adiabatic coupling adhesives, such as the epoxy-based and/or polyimide-based, ultraviolet (UV) curable adhesives described in detail below. Joining the photonic integrated circuit 1010 and the optical waveguides 1014 at the beginning of the process before other assembly of the optical module 1000 is performed makes this a photonic integrated circuit-first process. An alternative, photonic integrated circuit-last process will also be provided below. As provided above, suitable optical waveguides 1014 include, but are not limited to, polymer optical waveguides, glass optical waveguides, Si optical waveguides (e.g., Si with SiO₂ cladding and/or SiN with SiO₂ cladding optical waveguides), and/or alternate material waveguides such as BaTiO₃ and/or LiNbO₃ optical waveguides.

In step 2004, the photonic integrated circuit 1010 (with the optical waveguides 1014 attached) is then joined to the substrate 1006. As provided above, the photonic integrated circuit 1010 is joined to the substrate 1006 via the solder bumps 1008 (e.g., C4 connections). The solder bumps 1008 may then be encapsulated in underfill material 1009 for enhanced strength and performance.

In step 2006, the lid 1012 is attached to the top of the photonic integrated circuit 1010 and the top of the substrate 1006. According to an exemplary embodiment, the lid 1012 is attached to the photonic integrated circuit 1010 and the substrate 1006 using particular adhesives, such as the epoxy-based and/or polyimide-based mechanical adhesives described in detail below.

In step 2008, the ferrule 1030 is connected to the end of the optical waveguides 1014 opposite the photonic integrated circuit 1010, and the ferrule 1030 is attached to the lid 1012. According to an exemplary embodiment, a mechanical adhesive (see below) is used to secure the optical waveguides 1014 to the ferrule 1030. As provided above, the socket 1032 may be attached to the lid 1012 above the photonic integrated circuit 1010. In that case, the ferrule 1030 can simply be plugged into the socket 1032 (with or without an adhesive) to attach the ferrule 1030 to the lid 1012.

FIG. 3 is a top-down view illustrating how the present optical module 1000 co-packages the photonic integrated circuit 1010 and the optical waveguides 1014 with a single mode fiber array 3002 via the ferrule 1030 and a complementary ferrule 3004. For clarity of depiction, some of the above-described components associated with the optical module 1000 are not shown, such as the lid 1012, the socket 1032, etc. In this particular example, the optical waveguides 1014 (e.g., polymer optical waveguides, glass optical waveguides and/or Si optical waveguides) are part of an optical fiber ribbon array 1015. However, embodiments are also provided herein, and described below where these optical fibers are employed individually and aligned, for example, via v-shaped grooves in the photonic integrated circuit 1010.

Specifically, referring to FIG. 3, it can be seen that the single mode fiber array 3002 goes into a (pluggable) ferrule 3004. For clarity, the terms ‘first’ and ‘second’ may also be used herein when referring to the ferrule 1030 and the ferrule 3004, respectively. As is known to those of skill in the art, a single mode fiber is an optical fiber that is designed to carry a single, transverse mode of light, i.e., perpendicular to the propagation direction. Similarly, the optical waveguides 1014 go into the ferrule 1030. Thus, by coupling the ferrule 1030 with the ferrule 3004 (see arrow 3006), the ends of the optical waveguides 1014 are coupled to the ends of the fibers in the single mode fiber array 3002.

As above, one/first end of the optical waveguides 1014 is attached to the photonic integrated circuit 1010 and another/second end of the optical waveguides 1014 is attached to the ferrule 1030. Specifically, as shown in FIG. 3, there is a waveguide 3008 that is part of the photonic integrated circuit 1010 (shown with a dashed outline since it is not visible from the top-down), which is surrounded by a keep-out zone 3010. The optical waveguides 1014 are attached to this waveguide 3008 of the photonic integrated circuit 1010.

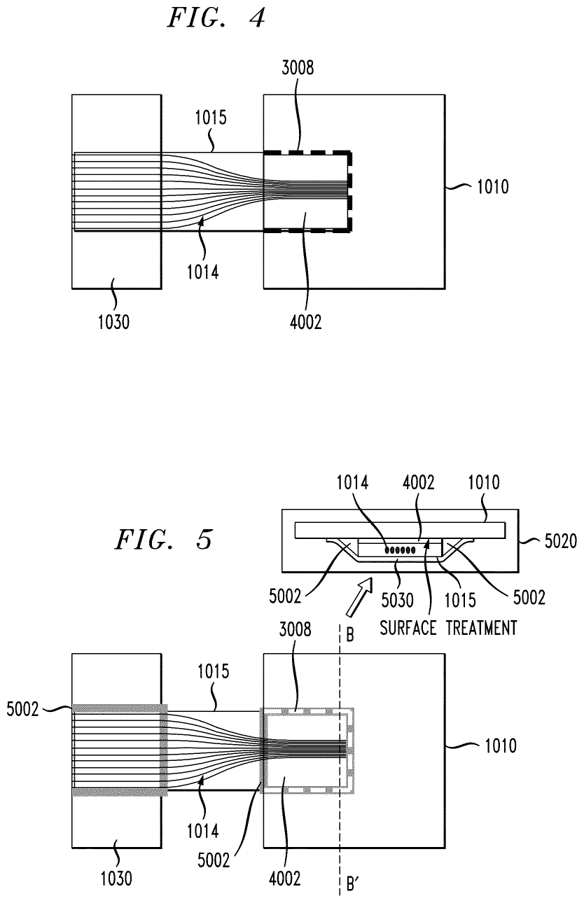

For instance, referring briefly to FIG. 4 and FIG. 5, according to an exemplary embodiment, the optical waveguides 1014 are attached to the waveguide 3008 of the photonic integrated circuit 1010 using an adiabatic coupling adhesive 4002 thereby achieving adiabatic coupling of the optical waveguides 1014 to the waveguide 3008. Suitable adhesives, including epoxy-based and/or polyimide-based UV curable adhesives, for use as the adiabatic coupling adhesive 4002 are described in detail below. Optionally, as shown in FIG. 5, an additional mechanical adhesive 5002 can be used to reinforce the junction between the optical waveguides 1014 and the waveguide 3008 and/or the junction between the optical waveguides 1014 and the ferrule 1030. Doing so adds mechanical integrity to these junctions, and enhances solder reflow and reliability stress compatibility. For instance, referring to inset 5020, which is a cross-section taken along line B-B′, the adiabatic coupling adhesive 4002 is present between the bottom- and top-facing surfaces of the photonic integrated circuit 1010 and the optical waveguides 1014, respectively. The mechanical adhesive 5002 is present along the edges of the optical waveguides 1014. Thus, the mechanical adhesive 5002 may also be referred to herein as an ‘edge adhesive.’ As will be described in detail below, while different adhesives may be used as the adiabatic coupling adhesive 4002 and the mechanical adhesive 5002, embodiments are also contemplated herein where the same adhesive is used for both. For instance, by way of example only, in some cases the same epoxy-based and/or polyimide-based UV curable adhesive is employed as the adiabatic coupling adhesive 4002 and the mechanical adhesive 5002. As will be described in detail below, an optional surface sealant 5030 can be employed to enhance reflow and reliability compatibility and/or an optional surface treatment of the photonic integrated circuit 1010 can be employed to reduce insertion loss.

Referring back to FIG. 3, the optical waveguides 1014 overlap some distance (e.g., from about 0.5 millimeter (mm) to about 3 mm) on the photonic integrated circuit 1010. Sec, for example, arrow 1040 in FIG. 1. This overlap enables adiabatic coupling of the optical waveguides 1014 with the waveguide 3008 of the photonic integrated circuit 1010. It is notable that, in this example, the optical waveguides 1014 are attached to a bottom of the photonic integrated circuit 1010, and thus the overlap is not visible from the top-down. A region 3012 contains the solder bumps 1008 (e.g., C4 connections), also not visible in the top-down. Thus, for instance, the cross-sectional view of the present optical module 1000 shown in FIG. 1 may be taken along line A-A′.

With this co-packaged design, the optical waveguides 1014 can go from a first/smaller pitch P1 (e.g., a pitch of about 20 micrometers (μm)) on the photonic integrated circuit 1010 side, and fan out to a second/larger pitch P2 (e.g., a pitch of from about 200 μm to about 250 μm) on the ferrule 1030 side, i.e., P1<P2. See arrows 3020 and 3022, respectively. That way, if the single mode fiber array 3002 has a standard pitch of from about 200 μm to about 250 μm, then it can be attached to the photonic integrated circuit 1010 via the optical waveguides 1014 through the ferrule 3004 and the ferrule 1030.

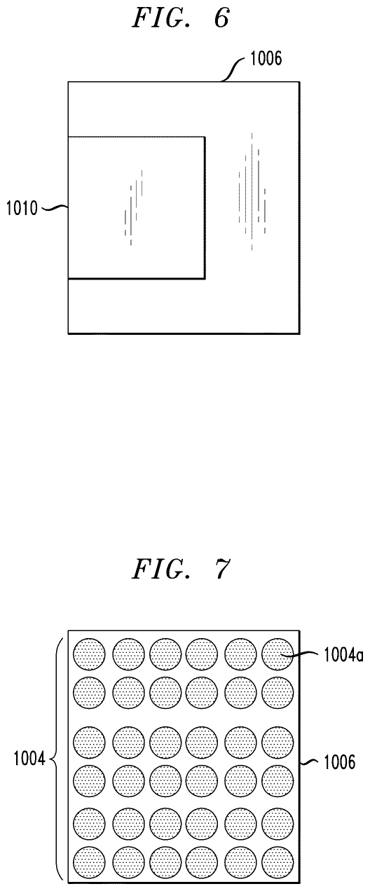

FIG. 6 is a diagram showing the top of the photonic integrated circuit 1010 and the substrate 1006. FIG. 7 is a diagram showing the bottom of the substrate 1006 having the ball grid array 1004 with its corresponding solder balls 1004a. Notably, in an alternative embodiment described in detail below, a photonic integrated circuit last fabrication process is employed and a cut-out is provided in the substrate 1006 for access to the photonic integrated circuit 1010 by the optical waveguides 1014.

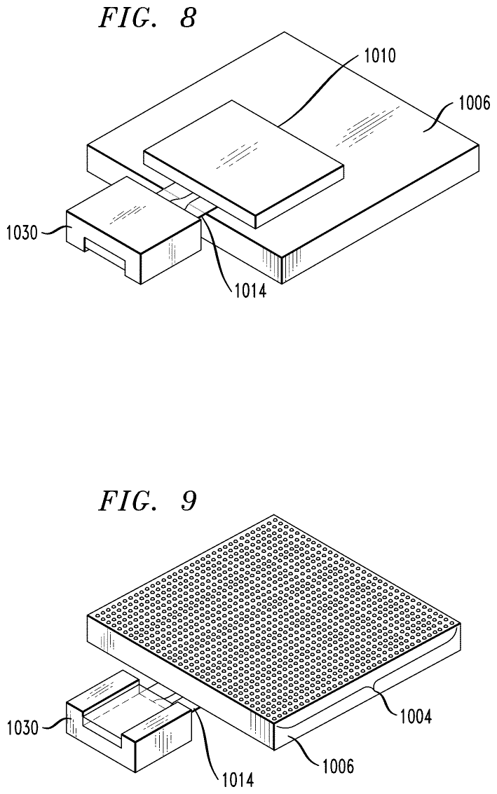

FIG. 8 and FIG. 9 are three-dimensional depictions of the optical module 1000. Namely, FIG. 8 shows the top of the optical module 1000 including the photonic integrated circuit 1010 attached to the substrate 1006, and the optical waveguides 1014 one/first end of which is attached to the photonic integrated circuit 1010 and another/second end of which is attached to the ferrule 1030. Again, structures such as the lid 1012 are not shown for clarity of depiction. FIG. 9 shows the bottom of the optical module 1000 including the bottom of the substrate 1006 having the ball grid array 1004.

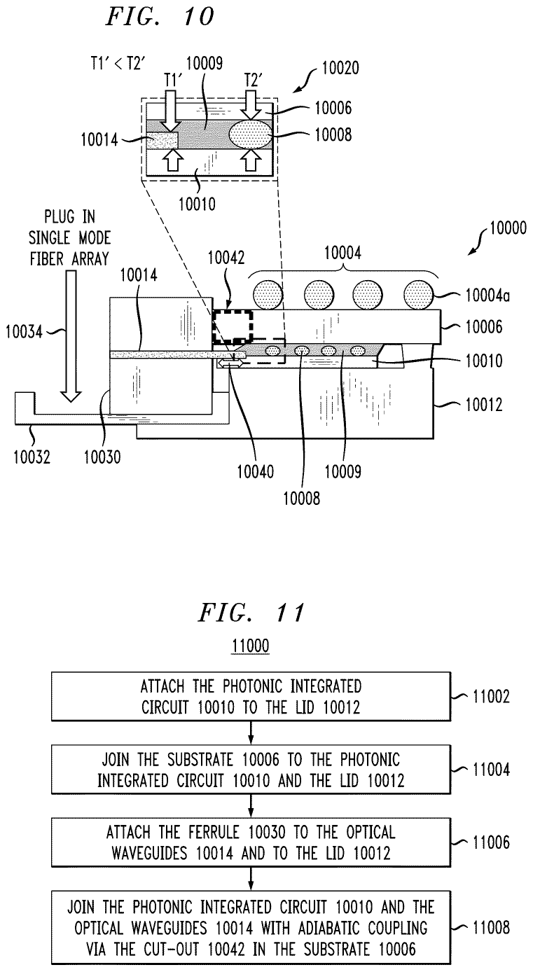

As highlighted above, embodiments are also contemplated herein where a photonic integrated circuit-last process is employed for fabricating the present the optical module, whereby the photonic integrated circuit and the optical waveguides are joined later on in the process. This alternative embodiment is now described by way of reference to FIGS. 10-18.

For instance, an optical module 10000 built using a photonic integrated circuit-last process is shown in FIG. 10. Optical module 10000 includes a lid 10012, a photonic integrated circuit 10010 disposed on the lid 10012, a substrate 10006 over and attached to the photonic integrated circuit 10010 via solder bumps 10008, where the substrate 10006 has a ball grid array or BGA 10004 (e.g., array of solder balls 10004a) on a top thereof. With this configuration, the lid 10012 is in direct contact with both the bottom of the photonic integrated circuit 10010 and the bottom of the substrate 10006 such that the photonic integrated circuit 10010 is present in between the substrate 10006 and the lid 10012. Thus, as with the previous example, the substrate 10006 is attached to the photonic integrated circuit 10010, and the lid 10012 directly contacts both the photonic integrated circuit 10010 and the substrate 10006. Here however, the lid 10012 contacts the bottoms of the photonic integrated circuit 10010 and the substrate 10006.

Also as above, the substrate 10006 can generally be any type of material commonly used for a printed circuit board core such as a dielectric material. According to an exemplary embodiment, the substrate 10006 is attached to the photonic integrated circuit 10010 using the solder bumps 10008 via a flip chip process or C4 connections. The solder bumps 10008 are then encapsulated in an underfill material 10009 such as an electrically-insulating adhesive for enhanced bonding strength, enhanced reliability stress performance and product performance. The lid 10012 can be formed of any suitable material that provides the structural integrity needed to hold the optical module 10000 together including, but not limited to, metals such as steel, aluminum and/or copper.

As shown in FIG. 10, optical waveguides 10014 (one of which is shown in cross-section) are attached to the photonic integrated circuit 10010. Hence, optical waveguides 10014 may also be referred to herein as ‘photonic integrated circuit optical waveguides.’ Suitable optical waveguides 10014 include, but are not limited to, polymer optical waveguides, glass optical waveguides, Si optical waveguides, e.g., optical waveguides known in the art containing Si with SiO₂ cladding and/or SiN with SiO₂ cladding, and/or alternate material waveguides such as BaTiO₃ and/or LiNbO₃ optical waveguides. According to an exemplary embodiment, the optical waveguides 10014 are thinner than the (C4 connection) solder bumps 10008 between the photonic integrated circuit 10010 and the substrate 10006. For instance, referring to magnified view 10020, the optical waveguides 10014 have a thickness T1′ and the solder bumps 10008 have a thickness T2′, where T1′<T2′. That way, the optical waveguides 10014 do not contact the substrate 10006 (i.e., the optical waveguides 10014 are in a non-contact position relative to the substrate 10006), thus avoiding the risk of compressing or pinching the optical waveguides 10014 during assembly.

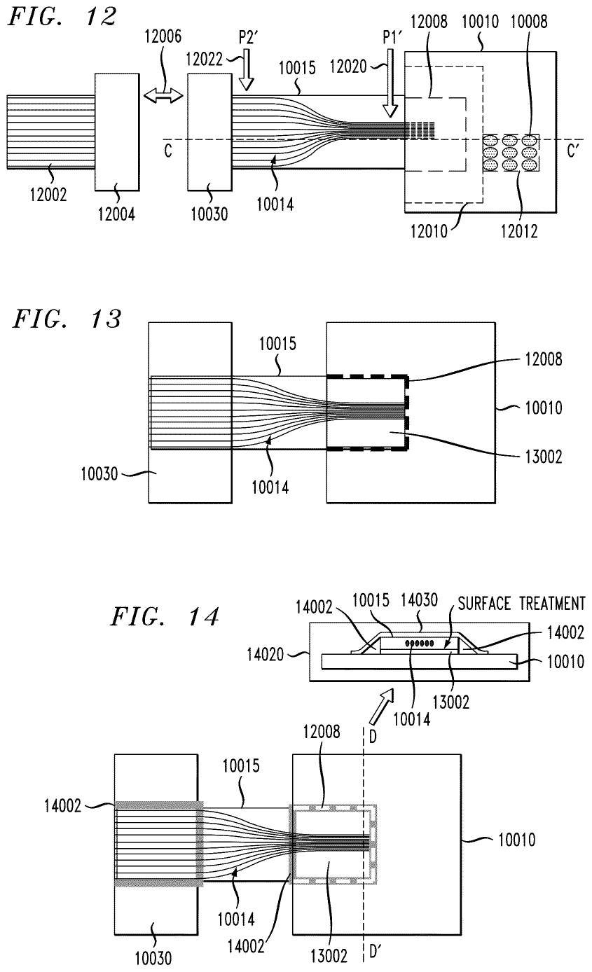

As shown in FIG. 10, one/first end of the optical waveguides 10014 is attached to the photonic integrated circuit 10010 and another/second end of the optical waveguides 10014 is attached to a ferrule 10030 at an edge of the optical module 10000. As will be described in detail below, a cut-out 10042 is provided in the substrate 10006 in order to access and attach the optical waveguides 10014 to the photonic integrated circuit 10010 at the last step of the assembly process. In the same manner as above, the ferrule 10030 will serve as a means for connecting (i.e., physically/optically joining) the optical waveguides 10014 to a single mode fiber array (see, for example, FIG. 12, below). In that regard, a socket 10032 is also attached to the lid 10012 below the photonic integrated circuit 10010 into which the ferrule 10030 is plugged. Namely, as indicated by arrow 10034, when a corresponding ferrule attached to the single mode fiber array is also plugged into the socket 10032, it will align with ferrule 10030 thereby joining the optical waveguides 10014 to the single mode fiber array.

As highlighted above, in this example the optical module 10000 is formed via a photonic integrated circuit-last process, whereby the optical waveguides 10014 are attached to the photonic integrated circuit 10010 in the last step of the assembly process via the cut-out 10042. See, for instance, exemplary methodology 11000 in FIG. 11.

Namely, in step 11002, the photonic integrated circuit 10010 is attached to the lid 10012. According to an exemplary embodiment, the photonic integrated circuit 10010 is attached to the lid 10012 using the epoxy-based and/or polyimide-based mechanical adhesives described below.

In step 11004, the substrate 10006 is then joined to the photonic integrated circuit 10010. As provided above, the substrate 10006 is joined to the photonic integrated circuit 10010 via the solder bumps 10008 (e.g., C4 connections). The solder bumps 10008 may then be encapsulated in the underfill material 10009 for enhanced strength and performance. The substrate 10006 may also be joined to the lid 10012 in this step using, e.g., the epoxy-based and/or polyimide-based mechanical adhesives described below.

In step 11006, the ferrule 10030 is attached to an end of the optical waveguides 1014, and the ferrule 10030 is attached to the lid 10012. A (e.g., epoxy-based and/or polyimide-based) mechanical adhesive can be used to secure the optical waveguides 10014 to the ferrule 10030. As provided above, the socket 10032 may be attached to the lid 10012 below the photonic integrated circuit 10010. In that case, the ferrule 10030 can simply be plugged into the socket 10032 (with or without an adhesive) to attach the ferrule 10030 to the lid 10012. As provided above, suitable optical waveguides 10014 include, but are not limited to, polymer optical waveguides, glass optical waveguides, Si optical waveguides (e.g., Si with SiO₂ cladding and/or SiN with SiO₂ cladding optical waveguides), and/or alternate material waveguides such as BaTiO₃ and/or LiNbO₃ optical waveguides.

In step 11008, the photonic integrated circuit 10010 and the optical waveguides 10014 are joined with adiabatic coupling. Since this is a photonic integrated circuit-last process, access by the optical waveguides 10014 to the photonic integrated circuit 10010 is provided via the cut-out 10042 in the substrate 10006. According to an exemplary embodiment, such adiabatic coupling is achieved through the use of adiabatic coupling adhesives, such as the epoxy-based and/or polyimide-based UV curable adhesives described in detail below.

FIG. 12 is a top-down view illustrating how the present optical module 11000 co-packages the photonic integrated circuit 10010 and the optical waveguides 10014 with a single mode fiber array 12002 via the ferrule 10030 and a complementary ferrule 12004. For clarity of depiction, some of the above-described components associated with the optical module 10000 are not shown, such as the lid 10012, the socket 10032, etc. In this particular example, the optical waveguides 10014 (e.g., polymer optical waveguides, glass optical waveguides and/or Si optical waveguides) are part of an optical fiber ribbon array 10015. However, embodiments are also provided herein, and described below where these optical fibers are employed individually and aligned, for example, via v-shaped grooves in the photonic integrated circuit 10010.

Specifically, referring to FIG. 12, it can be seen that the single mode fiber array 12002 goes into a (pluggable) ferrule 12004. For clarity, the terms ‘first’ and ‘second’ may also be used herein when referring to the ferrule 10030 and the ferrule 12004, respectively. Similarly, the optical waveguides 10014 go into the ferrule 10030. Thus, by coupling the ferrule 10030 with the ferrule 12004 (see arrow 12006), the ends of the optical waveguides 10014 are coupled to the ends of the fibers in the single mode fiber array 12002.

As described above, one/first end of the optical waveguides 10014 is attached to the photonic integrated circuit 10010 and another/second end of the optical waveguides 10014 is attached to the ferrule 10030. Specifically, as shown in FIG. 12, there is a waveguide 12008 that is part of the photonic integrated circuit 10010, which is surrounded by a keep-out zone 12010. The optical waveguides 10014 are attached to this waveguide 12008 of the photonic integrated circuit 10010.

For instance, referring briefly to FIG. 13 and FIG. 14, according to an exemplary embodiment, the optical waveguides 10014 are attached to the waveguide 12008 of the photonic integrated circuit 10010 using an adiabatic coupling adhesive 13002 thereby achieving adiabatic coupling of the optical waveguides 10014 to the waveguide 12008. Suitable adhesives, including epoxy-based and/or polyimide-based UV curable adhesives, for use as the adiabatic coupling adhesive 13002 are described in detail below. Optionally, as shown in FIG. 14, an additional (e.g., epoxy-based and/or polyimide-based) mechanical adhesive 14002 can be used to reinforce the junction between the optical waveguides 10014 and the waveguide 12008 and/or the junction between the optical waveguides 10014 and the ferrule 10030. Doing so adds mechanical integrity to these junctions, and enhances reflow and reliability stress compatibility. For instance, referring to inset 14020, which is a cross-section taken along line D-D′, the adiabatic coupling adhesive 13002 is present between the top- and bottom-facing surfaces of the photonic integrated circuit 10010 and the optical waveguides 10014, respectively. The mechanical adhesive 14002 is present along the edges of the optical waveguides 10014. Thus, the mechanical adhesive 14002 may also be referred to herein as an ‘edge adhesive.’ As will be described in detail below, while different adhesives may be used as the adiabatic coupling adhesive 13002 and the mechanical adhesive 14002, embodiments are also contemplated herein where the same adhesive is used for both. For instance, by way of example only, in some cases the same epoxy-based and/or polyimide-based UV curable adhesive is employed as the adiabatic coupling adhesive 13002 and the mechanical adhesive 14002. As will be described in detail below, an optional surface sealant 14030 can be employed to enhance reflow and reliability compatibility and/or an optional surface treatment of the photonic integrated circuit 10010 can be employed to reduce insertion loss.

Referring back to FIG. 12, the optical waveguides 10014 overlap some distance (e.g., from about 0.5 mm to about 3 mm in this example and waveguide dimensions) on the photonic integrated circuit 10010. See, for example, arrow 10040 in FIG. 10. This overlap enables adiabatic coupling of the optical waveguides 10014 with the waveguide 12008 of the photonic integrated circuit 10010. A region 12012 contains the solder bumps 10008 (e.g., C4 connections). Thus, for instance, the cross-sectional view of the present optical module 10000 shown in FIG. 10 may be taken along line C-C′.

With this co-packaged design, the optical waveguides 10014 can go from a first/smaller pitch P1′ (e.g., a pitch of about 20 μm) on the photonic integrated circuit 10010 side, and fan out to a second/larger pitch P2′ (e.g., a pitch of from about 200 μm to about 250 μm) on the ferrule 10030 side, i.e., P1′<P2′. See arrows 12020 and 12022, respectively. That way, if the single mode fiber array 12002 has a standard pitch of from about 200 μm to about 250 μm, then it can be attached to the photonic integrated circuit 10010 via the optical waveguides 10014 through the ferrule 12004 and the ferrule 10030.

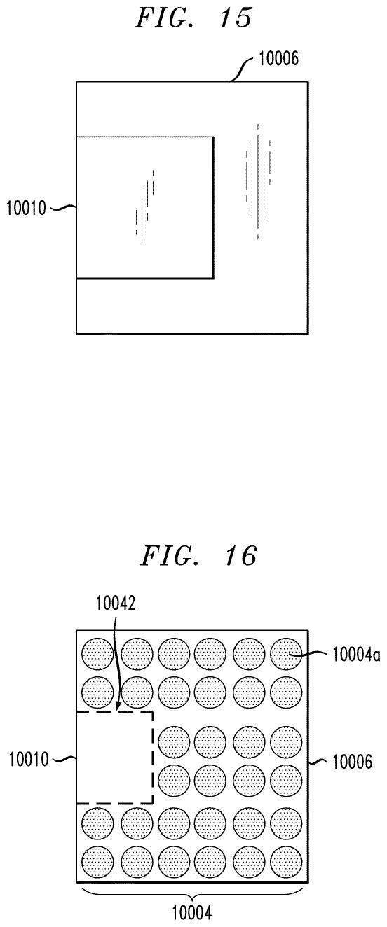

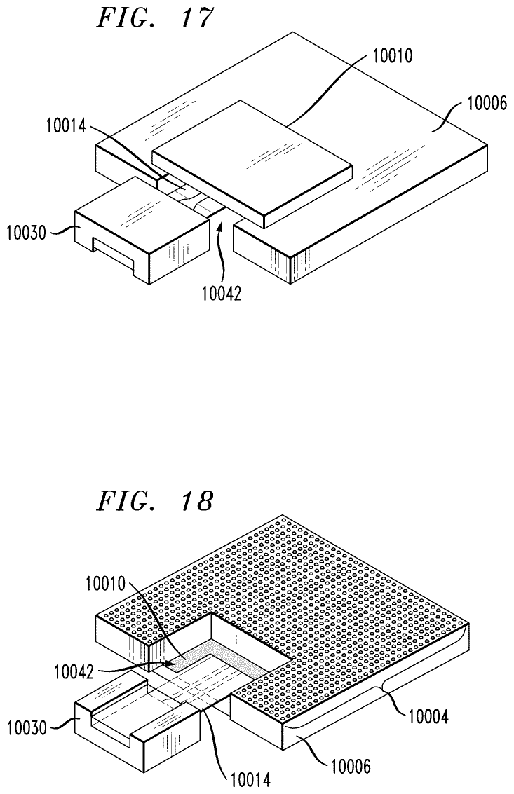

FIG. 15 is a diagram showing the bottom of the photonic integrated circuit 10010 and the substrate 10006. FIG. 16 is a diagram showing the top of the substrate 10006 having the ball grid array 10004 with its corresponding solder balls 10004a, and the cut-out 10042 over the photonic integrated circuit 10010 which provides access by the optical waveguides 10014 to the photonic integrated circuit 10010.

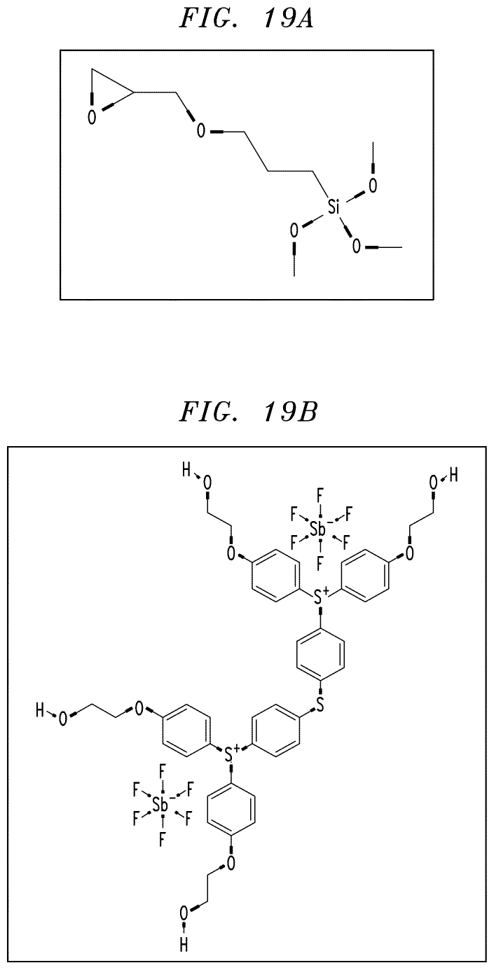

FIG. 17 and FIG. 18 are three-dimensional depictions of the optical module 10000. Namely, FIG. 17 shows the bottom of the optical module 10000 including the photonic integrated circuit 10010 attached to the substrate 10006, and the optical waveguides 10014 one/first end of which is attached to the photonic integrated circuit 10010 and another/second end of which is attached to the ferrule 10030. Again, structures such as the lid 10012 are not shown for clarity of depiction. Access by the optical waveguides 10014 to the photonic integrated circuit 10010 is provided via the cut-out 10042 in the substrate 10006. FIG. 18 shows the top of the optical module 10000 including the top of the substrate 10006 having the ball grid array 10004, and the cut-out 10042 providing access by the optical waveguides 10014 to the photonic integrated circuit 10010.

Reference is made above to use of an adiabatic coupling adhesive for adiabatic coupling of the optical waveguides 1014/optical waveguides 10014 with the waveguide 3008/waveguide 12008 of the photonic integrated circuit 1010/photonic integrated circuit 10010. More specifically, the adiabatic coupling adhesives employed herein advantageously have the following properties. First, the adiabatic coupling adhesives employed herein provide excellent bonding strength between the optical waveguides 1014/optical waveguides 10014 and the waveguide 3008/waveguide 12008 of the photonic integrated circuit 1010/photonic integrated circuit 10010. For example, samples that failed with mechanical peel strength of >0.25 Newtons/millimeter (mm) had higher adhesive strength than the cohesive mechanical test strips tested and showed good adhesion with reflow and reliability. In other examples, samples which had mechanical peel strength of >0.1-0.2 Newtons/mm but did not break the mechanical test strips also showed good adhesive characteristics including reflow and reliability. Second, the adiabatic coupling adhesives employed herein are preferably curable using electromagnetic radiation (such as UV light) at or near room temperature, with or without an additional thermal post-cure. A thermal post-cure of optical adhesives helps to increase reticulation, which increases adhesion. By way of example only, in accordance with the present techniques, ‘room temperature’ is a temperature of from about 15 degrees Celsius (° C.) to about 25° C., and ‘near room temperature’ represents a deviation from room temperature of up to ±5° C. Thus, for instance, temperatures in the range of from about 10° C. to about 30° C. are considered herein to be ‘at or near room temperature.’ It is notable that a room temperature cure is preferred when the coefficient of thermal expansion (CTE) between the waveguide and the photonic integrated circuit is used to minimize stress. For example, use of a polymer optical waveguide such as polyimide, fluorinated polyimide or alternate polymer joined using UV cure adhesive at room temperature has low or no stress at room temperature. Even if that room temperature UV cured sample is then taken to elevated temperatures for some small percent of additional cure, the stress as the sample goes back to room temperature is much smaller than if the polymer optical waveguide and the photonic integrated circuit are heated and the coefficient of thermal expansion (CTE) mismatch for a high temperature curing sample is then brought back to room temperature-because the CTE mismatch creates a stress between the high temperature bonded optical waveguide and the photonic integrated circuit as the sample is returned to room temperature causing higher stress. The present adiabatic coupling adhesives have good wettability, low wetting angle for adhesive to surface and low viscosity (e.g., <<1000 poise). Further, the surface of the optical waveguide and the photonic integrated circuit can be activated such as with use of plasma activation to improve adhesive bonding to radical OH bonds or other surface bonds enhanced with surface activation.

Third, the adiabatic coupling adhesives employed herein have a refractive index (RI) with a match or near match to that of the optical waveguides 1014/optical waveguides 10014 and the waveguide 3008/waveguide 12008 of the photonic integrated circuit 1010/photonic integrated circuit 10010, and also support reflow temperatures (such as those for the reflow of lead-free solder, e.g., from about 250° C. to about 260° C.). By way of example only, a refractive index with a near match would be a refractive index that is close to the refractive index of the optical waveguides 1014/optical waveguides 10014 core, and lower than the refractive index of the waveguide 3008/waveguide 12008 core of the photonic integrated circuit 1010/photonic integrated circuit 10010, such that the difference in refractive index (if any) results in an increase in insertion loss from optical waveguide to photonic integrated circuit of less than or equal to about 0.05 decibels. For instance, a near matching refractive index for a waveguide with a refractive index of 1.50 could be an adhesive sample with a refractive index of from about 1.49 to about 1.51. Similarly, for thermal reflow (and/or for stress testing), it is desirable to see no refractive index change and no insertion loss change with one or more cycles of reflow and reliability stress testing. Ranges of refractive index as per reflow above and stress test change in insertion loss are desired to not change or to have minimal change such as a refractive index change of <<0.01 and insertion loss of <0.1 decibels. Similarly, the adiabatic coupling adhesives employed herein have little to no change in adhesion or refractive index, nor change in shape, color, etc. of the respective structures. Preferably, these refractive index and reflow compatibility metrics are met when the present adiabatic coupling adhesives are employed between the optical waveguides 1014/optical waveguides 10014 and the waveguide 3008/waveguide 12008 of the photonic integrated circuit 1010/photonic integrated circuit 10010 at a thickness of less than about 2 μm, e.g., at a thickness of less than about 0.01 μm.

Fourth, the resulting optical module 1000/optical module 10000 with any of the present adiabatic coupling adhesives exhibits near zero or low insertion loss increase post reflow and post reliability stressing such as with JEDEC stress parameters used for electronic packaging and optics packaging. As its name implies, insertion loss generally refers to the loss of signal power resulting from the insertion of a device in an optical fiber. By way of example only, an insertion loss of less than one decibel, e.g., less than 0.4 decibels, preferably less than 0.1 decibels is considered herein to be near zero or low insertion loss. As is known to those of skill in the art, the Joint Electron Device Engineering Counsel or JEDEC provides open standards for microelectronics such as stress parameters for electronic packaging and optics packaging like the ability to withstand deep thermal cycles (DTC), high temperature storage (HTS), temperature and humidity (T&H) bias, etc.

According to an exemplary embodiment, the present adiabatic coupling adhesives are epoxy-based, UV curable adhesives that include, for example, base (epoxy resin and oxetane resin) monomers. An example of the epoxy resin/oxetane resin having benzene rings with: short fluorinated moieties of trifluoromethyl groups (—CF₃) and 1 to 3 fluorine (—F) groups on a few positions on the benzene ring is shown.

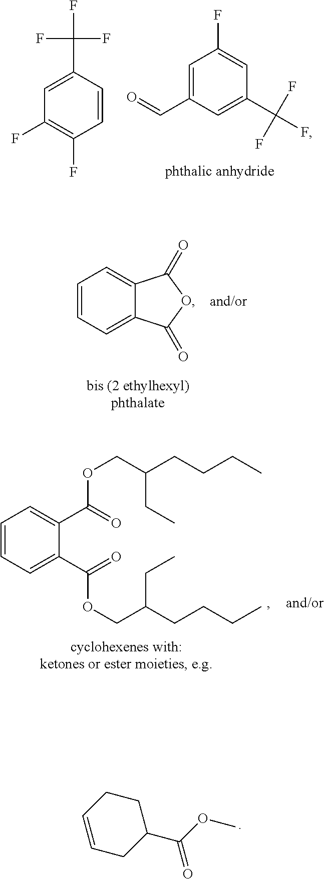

In one embodiment, a 2-penten-1 ol. i.e.,

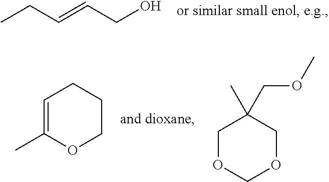

are used to adjust the adhesive refractive index, adhesive characteristics, viscosity, molecular chain length and/or temperature stability of the adhesive.

In another embodiment, propylene carbonate.

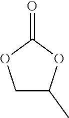

and cyclo 5-6-7 with 1 or no double bonds with various moieties.

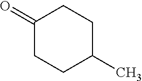

are used to adjust the adhesive refractive index, adhesive characteristics, viscosity, molecular chain length and/or temperature stability of the adhesive.

Optionally, the oxetane monomers are modified with adding fluorinated aromatic compounds. Doing so helps to optimize the properties of the adiabatic coupling adhesives. For instance, according to an exemplary embodiment, the present adiabatic coupling adhesives are configured to have a refractive index of from about 1.48 to about 1.52 (i.e., commensurate with that of a polymer optical waveguide), good adhesion, low viscosity and stability at (reflow) temperatures up to about 260° C. See above.

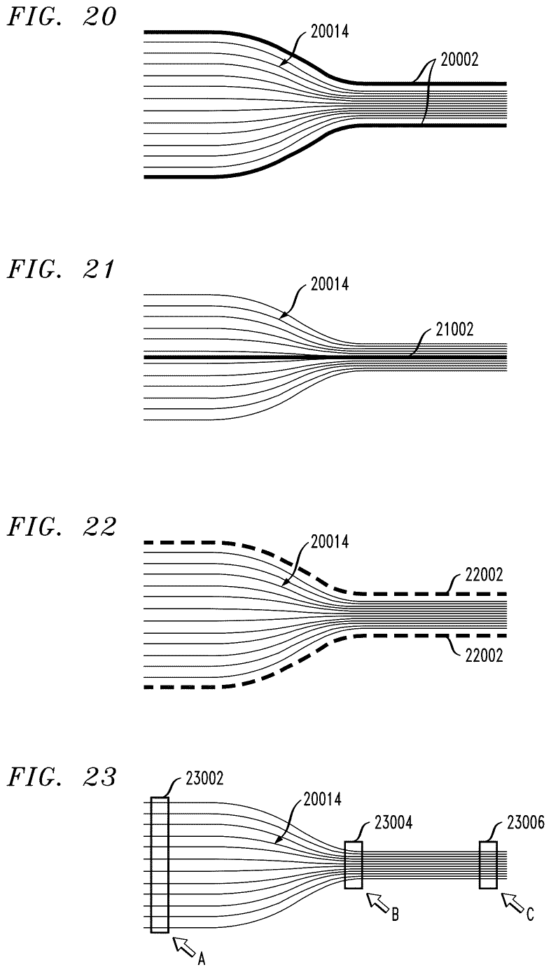

For instance, the base epoxy resin and oxetane resin monomers can be modified with a silane coupling agent and a 4,4′-Bis[di(β-hydroxyethoxy)Phenylsulfonio]phenylsulfide-bis-hexafluoroantimonate activator in order to reduce viscosity for improved material flow and to support higher temperature compatibility. See, for example, FIG. 19A and FIG. 19B. Namely, FIG. 19A is a schematic representation of trimethoxy [3-(oxiranylmethoxy)propyl] which is the base epoxy resin monomer modified with a silane coupling agent. FIG. 19B is a schematic representation of 4,4′-Bis[di(β-hydroxyethoxy)Phenylsulfonio]phenylsulfide-bis-hexafluoroantimonate which is the base oxetane resin monomer modified with an activator.

As highlighted above, any of these adiabatic coupling adhesives can also be used as the mechanical edge adhesive that enhances mechanical coupling at the junction of the optical waveguides 1014/10014 to the photonic integrated circuit 1010/10010 and/or at the junction of the optical waveguides 1014/10014 to the ferrule 1030/10030. Namely, while the mechanical edge adhesive does not need refractive index matching, the other requirements are the same as that for the adiabatic coupling adhesives, i.e., good adhesion, high temperature stability (e.g., at reflow temperatures up to about 260° C.), stress test (e.g., DTC, HTS, T&H) compatibility, etc. For clarity, the terms ‘first’ and ‘second’ may also be used herein when referring to the adiabatic coupling adhesive and the mechanical edge adhesive, respectively.

According to another exemplary embodiment, a polyimide-based adhesive is used as the adiabatic coupling adhesive. Optionally, a fluorinated polyimide-based adhesive may be used. Similarly, the polyimide-based adhesive can also be used as the mechanical edge adhesive that enhances mechanical coupling at the junction of the optical waveguides 1014/10014 to the photonic integrated circuit 1010/10010 and/or at the junction of the optical waveguides 1014/10014 to the ferrule 1030/10030. Further, combinations of these adhesives may be used such as an epoxy-based adhesive as the adiabatic coupling adhesive, and a polyimide-based adhesive as the mechanical edge adhesive, or vice versa.

Further, it has been observed herein that the mechanical properties of the optical waveguides (polymer optical waveguides, glass optical waveguides and/or Si optical waveguides) can degrade by up to about 50 percent (%) of their original strength when subject to reflow temperatures up to about 260° C., and even more so when the width of the optical waveguides is reduced (such as to create the above-described fan-out pattern). For instance, reducing the width of the optical waveguides from 3.5 millimeters (mm) to 0.9 mm reduces their strength by ¼ of 50% (when subject to reflow) or about 12.5% of their original strength.

In that regard, embodiments are also contemplated herein where optional strength enhancements are implemented to bolster the mechanical properties of the optical waveguides. See, for example, optical waveguides 20014 in FIGS. 20-23. Optical waveguides 20014 generally represent any of the above-described optical waveguides, e.g., optical waveguides 1014, optical waveguides 10014, etc., and like structures are numbered alike in the figures. For instance, as shown in FIG. 20, a metal wire 20002 can be disposed on either, or both, sides of the optical waveguides 20014. The metal wire 20002 can be round or flat (e.g., less than 50 μm thick and less than 100 μm wide), and composed of a metal such as, but not limited to, stainless steel, copper (Cu) and/or tungsten (W). The wire shape and/or material can be chosen based on strength properties, coefficient of thermal expansion (CTE), size, etc. In one exemplary embodiment, the metal wire 20002 can be attached to the optical waveguides 20014 using any of the above-described epoxy-based and/or polyimide-based adhesives.

Another option is to dispose a metal wire 21002 along a center of the optical waveguides 20014. See FIG. 21. Locating the metal wire 21002 at the center of the optical waveguides 20014 rather than on the sides can improve flex of the optical waveguides 20014. The metal wire 21002 can be round or flat (e.g., less than 50 μm thick and less than 100 μm wide), and composed of a metal such as, but not limited to, stainless steel, Cu and/or W. Embodiments are also contemplated herein where both side and center locations are employed, i.e., a metal wire 20002 disposed on a side(s) of the optical waveguides 20014 AND a metal wire 21002 disposed at a center of the optical waveguides 20014. Further in that regard, any of the strength enhancements described herein may be employed individually, or in combination with any other of the strength enhancements described herein.

A surface coating 22002 can also be deposited onto the optical waveguides 20014 as a strength enhancement. See FIG. 22. According to an exemplary embodiment, the surface coating 22002 is a composite of structures such as fibers, whiskers and/or flakes distributed in a polymer matrix.

Alternatively, or in addition to any combination of the above strength enhancements, crackstops 23002, 23004, 23006, etc. can be employed at one or more locations along the optical waveguides 20014. As its name implies, a ‘crackstop’ is a structure that prevents cracks or other breakages from forming and/or propagating in the optical waveguides 20014 by enhancing mechanical strength at stress points along the optical waveguides 20014. According to an exemplary embodiment, the crackstops 23002, 23004, 23006, etc. are formed by a mechanical adhesive disposed over and surrounding the optical waveguides 20014 at locations A, B, C, etc. Any of the above-described epoxy-based and polyimide-based adhesives can be employed as the crackstops 23002, 23004, 23006, etc. In one embodiment, locations A and B/C correspond to regions where the optical waveguides 20014 would attach to the ferrule (e.g., ferrule 1030, ferrule 10030, etc.) and where the optical waveguides 20014 would attach to the photonic integrated circuit (e.g., photonic integrated circuit 1010, photonic integrated circuit 10010, etc.). In that regard, as shown in FIG. 23, the crackstops 23002, 23004, 23006, etc. would taper from crackstop 23002 to crackstops 23004/23006 due to the fan-out pattern of the optical waveguides 20014.

As highlighted above, an optional surface sealant 5030/surface sealant 14030 can be employed to enhance reflow and reliability compatibility. See, for example, inset 5020 in FIG. 5 and inset 14020 in FIG. 14. According to an exemplary embodiment, the surface sealant 5030/surface sealant 14030 is formed from perylene (C₂₀H₁₂), titanium (Ti), titanium oxide (TiO₂), silicon nitride (SiN) and/or tantalum nitride (TaN). It has also been observed herein that when the optical waveguides (polymer optical waveguides, glass optical waveguides and/or Si optical waveguides) are subject to reflow temperatures up to about 260° C. there can be an increase in insertion loss. In that regard, as highlighted above, an optional surface treatment of the photonic integrated circuit 1010 can be employed to reduce insertion loss. See, for example, inset 5020 in FIG. 5 and inset 14020 in FIG. 14. According to an exemplary embodiment, the surface treatment includes the deposition of a layer of SiN, silicon dioxide (SiO₂), silicon oxycarbonitride (SiOCN) and/or TiO₂ onto the photonic integrated circuit 1010, photonic integrated circuit 10010, etc. prior to attaching the optical waveguides 1014, optical waveguides 10014, etc. For instance, plasma-treated SiN and SiO₂ exhibit high surface energy, enhancing wettability. This improved wettability facilitates easier application of adhesive to the surface. Namely, the adiabatic coupling adhesive 4002, adiabatic coupling adhesive 13002, etc. can then be placed over this surface treatment.

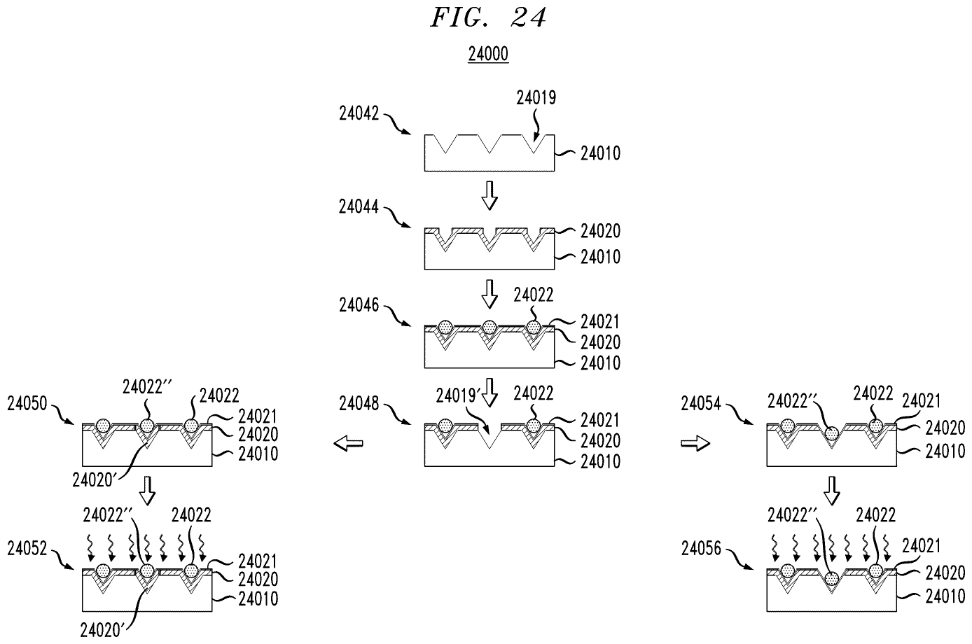

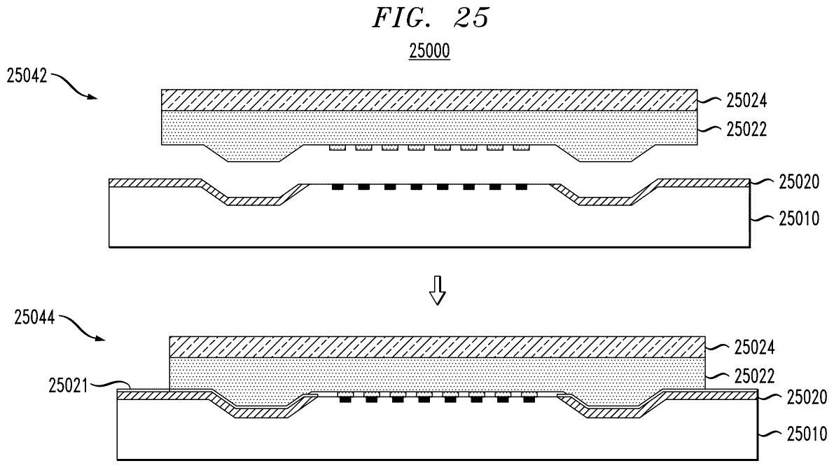

Embodiments are also contemplated herein where reworkable optical connections are employed, such as between the photonic integrated circuit 1010, photonic integrated circuit 10010, etc. and the optical waveguides 1014, optical waveguides 10014, etc. which enable the non-permanent connections therebetween to be released and defective components replaced. See, for instance, exemplary methodology 24000 in FIG. 24 (with optical fibers) and exemplary methodology 25000 in FIG. 25 (with an optical fiber ribbon array).

Namely, referring first to methodology 24000 in FIG. 24, a scenario is depicted where glass fibers 24022 are attached to a photonic integrated circuit 24010 via reworkable optical connections. Photonic integrated circuit 24010 is representative of any of the above-described photonic integrated circuits, i.e., photonic integrated circuit 1010, photonic integrated circuit 10010, etc., and glass fibers 24022 are representative of any of the above-described optical waveguides, i.e., optical waveguides 1014, optical waveguides 10014, etc.

In step 24042, the photonic integrated circuit 24010 is provided having v-shaped grooves 24019 in a (e.g., top) surface thereof. As will become apparent from the description that follows, these v-shaped grooves 24019 will serve to properly align the glass fibers 24022 along the top surface of the photonic integrated circuit 24010.

In step 24044, a release layer 24020 is deposited onto the top surface of the photonic integrated circuit 24010 including within the v-shaped grooves 24019. The release layer 24020 will enable the formation of reworkable optical connections. According to an exemplary embodiment, the release layer 24020 is formed from a material having an electro-magnetic radiation absorption level that permits adhesive curing at room temperature within from about 30 seconds to about 10 minutes, preferably from about 30 seconds to about 3 minutes, such as, but not limited to, carbon, titanium (Ti), aluminum (Al) and/or copper (Cu), where electro-magnetic radiation absorption of the release layer 24020 is matched to wavelength of targeted release electro-magnetic radiation for subsequent rework.

In step 24046, glass fibers 24022 are bonded to the photonic integrated circuit 24010 using an adiabatic coupling adhesive 24021 (e.g., an epoxy-based or a polyimide-based adhesive) in the same manner as above. Only, in this example, the adiabatic coupling adhesive 24021 is placed over the release layer 24020, and the glass fibers 24022 are placed in the v-shaped grooves 24019.

In step 24048, one or more of the glass fibers 24022 are selectively removed via the release layer 24020. In this particular example, it is a select one of the glass fibers 24022 in v-shaped groove 24019′. As highlighted above, the release layer 24020 in this example is configured to ‘release’ its bond to the top surface of the photonic integrated circuit 24010 when subject to electro-magnetic radiation such as UV or infrared light and/or laser which, in this example, is directed at v-shaped groove 24019′. Once the select one of the glass fibers 24022 has been released and removed from the v-shaped groove 24019′, a suitable solvent can then be used to selectively remove the adiabatic coupling adhesive 24021 from the v-shaped groove 24019′.

The select one of the glass fibers 24022 that has been removed from the v-shaped groove 24019′ can then be replaced with a different, new glass fiber 24022′ or 24022″. Namely, the new glass fiber 24022′ can be added to the v-shaped groove 24019′ with an additional release layer 24020′, and the adiabatic coupling adhesive 24021 (step 24050), followed by a UV and/or thermal cure (step 24052). Alternatively, the new glass fiber 24022″ can be added to the v-shaped groove 24019′ with simply the adiabatic coupling adhesive 24021 (step 24054), followed by a UV and/or thermal cure (step 24056).

A release layer 25020 can also be applied in the same manner for attaching an optical fiber ribbon array 25022 to a photonic integrated circuit 25010 with reworkable optical connections. See, for example, methodology 25000 in FIG. 25. Photonic integrated circuit 25010 is representative of any of the above-described photonic integrated circuits, i.e., photonic integrated circuit 1010, photonic integrated circuit 10010, etc., and the optical fiber ribbon array 25022 is representative of any of the above-described optical waveguides, i.e., optical waveguides 1014, optical waveguides 10014, etc. In this example, a stiffener plate 25024 is attached the optical fiber ribbon array 25022 for mechanical stability and to maintain uniformity. Suitable materials for the stiffener plate 25024 include, but are not limited to, glass, silicon (Si) and/or metal.

In step 25042, the release layer 25020 is deposited onto the photonic integrated circuit 25010. As above, the release layer 25020 can be formed from a material having a high electro-magnetic radiation absorption (see above) such as, but not limited to, carbon, Ti, Al and/or Cu where electro-magnetic radiation absorption of the release layer 25020 is matched to wavelength of targeted release electro-magnetic radiation for subsequent rework.

In step 25044, the optical fiber ribbon array 25022 is bonded to the photonic integrated circuit 25010 using an adiabatic coupling adhesive 25021 (e.g., an epoxy-based or a polyimide-based adhesive) in the same manner as above. Only, in this example, the adiabatic coupling adhesive 25021 is placed over the release layer 25020.

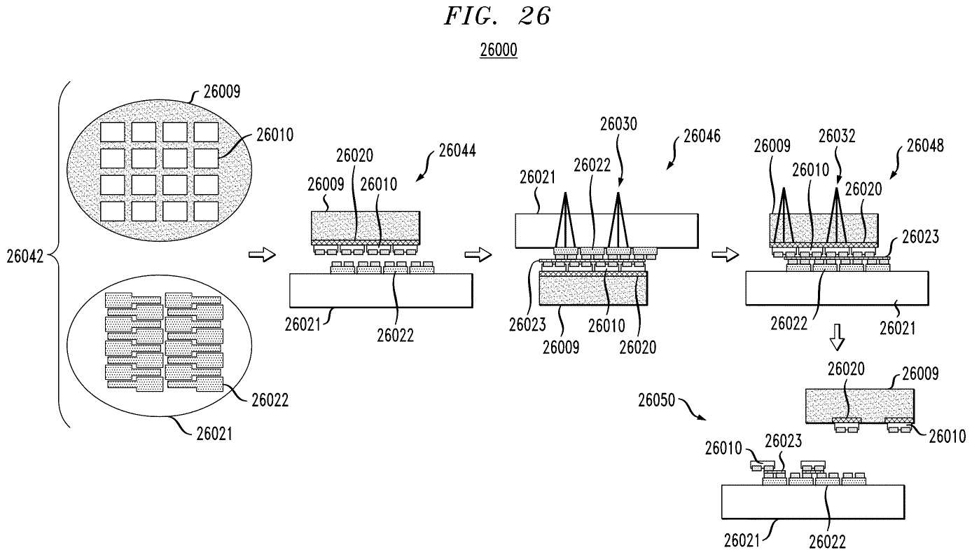

In accordance with the present techniques, a (electro-magnetic radiation releasable) release layer 26020 and a (UV curable) adiabatic coupling adhesive 26023 can also be leveraged to scale-up optical coupling of photonic integrated circuits 26010 and optical fiber ribbon arrays 26022. See, for example, methodology 26000 of FIG. 26. Photonic integrated circuits 26010 are representative of any of the above-described photonic integrated circuits, i.e., photonic integrated circuit 1010, photonic integrated circuit 10010, etc., and the optical fiber ribbon arrays 26022 are representative of any of the above-described optical waveguides, i.e., optical waveguides 1014, optical waveguides 10014, etc.

The process begins in step 26042 with a (e.g., Si) handle wafer 26009 with the photonic integrated circuits 26010 and a glass handle 26021 with the optical fiber ribbon arrays 26022, both shown in top-down views. Switching to cross-sectional views, in step 26044 the handle wafer 26009 and the glass handle 26021 are oriented in a face-to-face manner, i.e., with the photonic integrated circuits 26010 and the optical fiber ribbon arrays 26022 facing one another. Notably, the photonic integrated circuits 26010 are bonded to the handle wafer 26009 by the release layer 26020.

In step 26046, the photonic integrated circuits 26010 and the optical fiber ribbon arrays 26022 are aligned, and a UV curable adiabatic coupling adhesive 26023 (e.g., an epoxy-based or a polyimide-based adhesive, same as above) is used to bond select ones of the photonic integrated circuits 26010 and the optical fiber ribbon arrays 26022 together. For instance, a (e.g., 355 nanometer (nm)) laser 26030 can be used to individually cure the adiabatic coupling adhesive 26023 that is present between the select ones of the photonic integrated circuits 26010 and the optical fiber ribbon arrays 26022. As shown FIG. 26, this laser bonding occurs through the glass handle 26021.

In step 26048, a (e.g., 1.3 μm or 2.1 μm) IR laser 26032 is used selectively debond the photonic integrated circuits 26010 from the handle wafer 26009 which were bonded to the optical fiber ribbon arrays 26022 in step 26046. This laser debonding is enabled via the release layer 26020 and, as shown in FIG. 26, occurs through the handle wafer 26009.

In step 26050, the handle wafer 26009 is removed (along with unbonded ones of the photonic integrated circuits 26010), while the select ones of the photonic integrated circuits 26010 remain bonded to the optical fiber ribbon arrays 26022 on the glass handle 26021.

Optionally, the select ones of the photonic integrated circuits 26010 bonded to the optical fiber ribbon arrays 26022 can receive a resist coating and cure, followed by singulation such as with mechanical saw singulation, laser singulation, plasma singulation or combinations thereof, followed by a clean/wash step and resist strip process.

The present techniques are further described by way of reference to the following non-limiting examples:

Example 1 (epoxy-based or polyimide-based adiabatic coupling adhesives): for adiabatic coupling, an epoxy-based or polyimide-based adhesive was used with a thin bond line of less than (<) 1 micrometer (μm), and an ultraviolet (UV) cure at room temperature and/or a thermal cure (e.g., from about 100° C. to about 180° C. for about 1 hour). The result was high adhesion between the photonic integrated circuit and the optical waveguides (e.g., polymer optical waveguides, glass optical waveguides and/or Si optical waveguides). The refractive index was a match or near match (see above) to the photonic integrated circuit and the optical waveguides. The resulting optical module supported C4 and BGA reflow through multiple cycles, supported JEDEC testing for −55° C. to 125° C. at 1000 cycles, HTS at 150° C. or 125° C. for 1000 hours and 85° C./85 percent (%) relative humidity at 1000 hours, and supported low insertion loss at <0.1 decibels (dB) to <0.4 dB.

Example 2 (epoxy-based or polyimide-based mechanical edge adhesives): for mechanical coupling an epoxy-based or polyimide-based adhesive was used with a thin bond line, and a UV cure at room temperature and/or thermal cure (e.g., from about 100° C. to about 180° C. for about 1 hour). The result was high adhesion to join the ferrule to the optical waveguides (e.g., polymer optical waveguides, glass optical waveguides and/or Si optical waveguides). The resulting optical module supported C4 and BGA reflow through multiple cycles, supported JEDEC testing for −55° C. to 125° C. at 1000 cycles, HTS at 150° C. or 125° C. for 1000 hours and 85° C./85% relative humidity at 1000 hours.

Example 3 (epoxy-based or polyimide-based adiabatic coupling adhesives): for adiabatic coupling, an epoxy-based or polyimide-based adhesive was used with a thin bond line of <1 μm, and a UV cure at room temperature and/or thermal cure (e.g., from about 100° C. to about 180° C. for about 1 hour). The result was high adhesion between the photonic integrated circuit and the optical waveguides (e.g., polymer optical waveguides, glass optical waveguides and/or Si optical waveguides). The refractive index was a match or near match (see above) to the photonic integrated circuit and the optical waveguides. The resulting optical module supported C4 and BGA reflow through multiple cycles, supported JEDEC testing for −55° C. to 125° C. at 1000 cycles, HTS at 150° C. or 125° C. for 1000 hours and 85° C./85% relative humidity at 1000 hours, and supported low insertion loss at <0.1 dB to <0.4 dB. The optical module included second edge and/or surface adhesive or coating to enhance mechanical interlock and/or provide moisture seal for enhanced stability in multiple C4/BGA reflow and JEDEC reliability stress testing and product life. The optical module also included optional surface metal, seal of metal, peryleyene, solder and/or alternate seal which were applied to portions of the optical waveguides not already encapsulated by the ferrule or optical module, and thus would otherwise be exposed to air. For example, a full module can be fabricated using components and then coated with a metal seal such as a chemical vapor deposition (CVD) or plasma-enhanced CVD (PECVD) coating, or a spray or dip coating followed by an anneal and/or cure to seal the samples.

Example 4 (epoxy-based or polyimide-based mechanical edge adhesives): for mechanical coupling an epoxy-based or polyimide-based adhesive was used with a thin bond line, and a UV cure at room temperature and/or thermal cure (e.g., from about 100° C. to about 180° C. for about 1 hour). The result was high adhesion to join the ferrule to the optical waveguides (e.g., polymer optical waveguides, glass optical waveguides and/or Si optical waveguides). The resulting optical module supported C4 and BGA reflow through multiple cycles, supported JEDEC testing for −55° C. to 125° C. at 1000 cycles, HTS at 150° C. or 125° C. for 1000 hours and 85° C./85% relative humidity at 1000 hours. The optical module included second edge and/or surface adhesive or coating to enhance mechanical interlock and/or provide moisture seal for enhanced stability in multiple C4/BGA reflow and JEDEC reliability stress testing and product life. The optical module also included optional surface metal, seal of metal, peryleyene, solder and/or alternate seal which were applied to portions of the optical waveguides not already encapsulated by the ferrule or optical module, and thus would otherwise be exposed to air. For example, as provided above, a full module can be fabricated using components and then coated with a metal seal such as a CVD or PECVD coating, or a spray or dip coating followed by an anneal and/or cure to seal the samples.

Semiconductor device manufacturing includes various steps of device patterning processes. For example, the manufacturing of a semiconductor chip can start with, for example, a plurality of CAD (computer aided design) generated device patterns, which is then followed by effort to replicate these device patterns in a substrate. The replication process can involve the use of various exposing techniques and a variety of subtractive (etching) and/or additive (deposition) material processing procedures. For example, in a photolithographic process, a layer of photo-resist material can first be applied on top of a substrate, and then be exposed selectively according to a pre-determined device pattern or patterns. Portions of the photo-resist that are exposed to light or other ionizing radiation (e.g., ultraviolet, electron beams, X-rays, etc.) can experience some changes in their solubility to certain solutions. The photo-resist can then be developed in a developer solution, thereby removing the non-irradiated (in a negative resist) or irradiated (in a positive resist) portions of the resist layer, to create a photo-resist pattern or photo-mask. The photo-resist pattern or photo-mask can subsequently be copied or transferred to the substrate underneath the photo-resist pattern.

There are numerous techniques used by those skilled in the art to remove material at various stages of creating a semiconductor structure. As used herein, these processes are referred to generically as “etching”. For example, etching includes techniques of wet etching, dry etching, chemical oxide removal (COR) etching, and reactive ion etching (RIE), which are all known techniques to remove select material(s) when forming a semiconductor structure. The Standard Clean 1 (SC1) contains a strong base, typically ammonium hydroxide, and hydrogen peroxide. The SC2 contains a strong acid such as hydrochloric acid and hydrogen peroxide. The techniques and application of etching is well understood by those skilled in the art and, as such, a more detailed description of such processes is not presented herein.

Although the overall fabrication method and the structures formed thereby are novel, certain individual processing steps required to implement the method can utilize conventional semiconductor fabrication techniques and conventional semiconductor fabrication tooling. These techniques and tooling will already be familiar to one having ordinary skill in the relevant arts given the teachings herein. For example, the skilled artisan will be familiar with epitaxial growth, self-aligned contact formation, formation of high-K metal gates, and so on. The term “high-K” has a definite meaning to the skilled artisan in the context of high-K metal gate (HKMG) stacks, and is not a mere relative term. Moreover, one or more of the processing steps and tooling used to fabricate semiconductor devices are also described in a number of readily available publications, including, for example: James D. Plummer et al., Silicon VLSI Technology: Fundamentals, Practice, and Modeling 1^{st} Edition, Prentice Hall, 2001 and P. H. Holloway et al., Handbook of Compound Semiconductors: Growth, Processing, Characterization, and Devices, Cambridge University Press, 2008, which are both hereby incorporated by reference herein. It is emphasized that while some individual processing steps are set forth herein, those steps are merely illustrative, and one skilled in the art may be familiar with several equally suitable alternatives that would be applicable.

It is to be appreciated that the various layers and/or regions shown in the accompanying figures may not be drawn to scale. Furthermore, one or more semiconductor layers of a type commonly used in such integrated circuit devices may not be explicitly shown in a given figure for case of explanation. This does not imply that the semiconductor layer(s) not explicitly shown are omitted in the actual integrated circuit device.

Those skilled in the art will appreciate that the exemplary structures discussed above can be distributed in raw form (i.e., a single wafer having multiple unpackaged chips), as bare dies, in packaged form, or incorporated as parts of intermediate products or end products.

An integrated circuit in accordance with aspects of the present inventions can be employed in essentially any application and/or electronic system. Given the teachings of the present disclosure provided herein, one of ordinary skill in the art will be able to contemplate other implementations and applications of embodiments disclosed herein.

The illustrations of embodiments described herein are intended to provide a general understanding of the various embodiments, and they are not intended to serve as a complete description of all the elements and features of apparatus and systems that might make use of the circuits and techniques described herein. Many other embodiments will become apparent to those skilled in the art given the teachings herein; other embodiments are utilized and derived therefrom, such that structural and logical substitutions and changes can be made without departing from the scope of this disclosure. It should also be noted that, in some alternative implementations, some of the steps of the exemplary methods can occur out of the order noted in the figures. For example, two steps shown in succession may, in fact, be executed substantially concurrently, or certain steps may sometimes be executed in the reverse order, depending upon the functionality involved. The drawings are also merely representational and are not drawn to scale. Accordingly, the specification and drawings are to be regarded in an illustrative rather than a restrictive sense.

Embodiments are referred to herein, individually and/or collectively, by the term “embodiment” merely for convenience and without intending to limit the scope of this application to any single embodiment or inventive concept if more than one is, in fact, shown. Thus, although specific embodiments have been illustrated and described herein, it should be understood that an arrangement achieving the same purpose may be substituted for the specific embodiment(s) shown; that is, this disclosure is intended to cover any and all adaptations or variations of various embodiments. Combinations of the above embodiments, and other embodiments not specifically described herein, will become apparent to those of skill in the art given the teachings herein.

The terminology used herein is for the purpose of describing particular embodiments only and is not intended to be limiting. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, steps, operations, elements, and/or components, but do not preclude the presence or addition of one or more other features, steps, operations, elements, components, and/or groups thereof. Terms such as “bottom”, “top”, “above”, “over”, “under” and “below” are used to indicate relative positioning of elements or structures to each other as opposed to relative elevation. If a layer of a structure is described herein as “over” another layer, it will be understood that there may or may not be intermediate elements or layers between the two specified layers. If a layer is described as “directly on” another layer, direct contact of the two layers is indicated. As the term is used herein and in the appended claims, “about” means within plus or minus ten percent.

The corresponding structures, materials, acts, and equivalents of any means or step-plus-function elements in the claims below are intended to include any structure, material, or act for performing the function in combination with other claimed elements as specifically claimed. The description of the various embodiments has been presented for purposes of illustration and description, but is not intended to be exhaustive or limited to the forms disclosed. Many modifications and variations will be apparent to those of ordinary skill in the art without departing from the scope and spirit thereof. The embodiments were chosen and described in order to best explain principles and practical applications, and to enable others of ordinary skill in the art to understand the various embodiments with various modifications as are suited to the particular use contemplated.

The abstract is provided to comply with 37 C.F.R. § 1.76(b), which requires an abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the appended claims reflect, the claimed subject matter may lie in less than all features of a single embodiment. Thus, the following claims are hereby incorporated into the Detailed Description, with each claim standing on its own as separately claimed subject matter.

Given the teachings provided herein, one of ordinary skill in the art will be able to contemplate other implementations and applications of the techniques and disclosed embodiments. Although illustrative embodiments have been described herein with reference to the accompanying drawings, it is to be understood that illustrative embodiments are not limited to those precise embodiments, and that various other changes and modifications are made therein by one skilled in the art without departing from the scope of the appended claims.

What is claimed is:

1. An optical module, comprising:
a photonic integrated circuit attached to a substrate;
a lid in direct contact with the substrate such that the photonic integrated circuit is present in between the substrate and the lid;
optical waveguides attached to the photonic integrated circuit; and
a ferrule attached to the optical waveguides.

2. The optical module of claim 1, wherein the optical waveguides are selected from the group consisting of: polymer optical waveguides, glass optical waveguides, silicon optical waveguides, and combinations thereof.

3. The optical module of claim 1, wherein the optical waveguides fan out from a first pitch P1 at the photonic integrated circuit to a second pitch P2 at the ferrule, and wherein P1<P2.

4. The optical module of claim 1, wherein the ferrule attached to the optical waveguides is a first ferrule, and wherein the optical module further comprises:
a second ferrule attached to a single mode fiber array, wherein the second ferrule is coupled to the first ferrule.

5. The optical module of claim 1, wherein the optical waveguides are attached to the photonic integrated circuit using a first adhesive, and wherein the optical module further comprises:
a second adhesive disposed on one or more edges of the optical waveguides at least one of: a junction of the optical waveguides to the photonic integrated circuit and a junction of the optical waveguides to the ferrule.

6. The optical module of claim 5, wherein at least one of the first adhesive and the second adhesive comprises an epoxy-based adhesive.

7. The optical module of claim 6, wherein the epoxy-based adhesive comprises trimethoxy [3-(oxiranylmethoxy)propl].

8. The optical module of claim 7, wherein the epoxy-based adhesive comprises an oxetane resin monomer.

9. The optical module of claim 8, wherein the epoxy-based adhesive comprises 4,4′-Bis[di(β-hydroxyethoxy)Phenylsulfonio]phenylsulfide-bis-hexafluoroantimonate.

10. The optical module of claim 5, wherein at least one of the first adhesive and the second adhesive comprises a polyimide-based adhesive.

11. The optical module of claim 1, further comprising:
a metal wire disposed on the optical waveguides for strength enhancement at a location selected from the group consisting of: at least one side of the optical waveguides, a center of the optical waveguides, or combinations thereof.

12. The optical module of claim 1, further comprising:
a surface coating disposed on the optical waveguides for strength enhancement, the surface coating comprising a composite of structures selected from the group consisting of: fibers, whiskers, flakes, and combinations thereof distributed in a polymer matrix.

13. The optical module of claim 1, further comprising:
a crackstop at one or more locations along the optical waveguides for strength enhancement, wherein the crackstop comprises an adhesive disposed over, and surrounding, the optical waveguides.

14. The optical module of claim 1, further comprising:
a release layer between the optical waveguides and the photonic integrated circuit, wherein the release layer comprises a material selected from the group consisting of: carbon, titanium, aluminum, copper, and combinations thereof.

15. An optical module, comprising:
a photonic integrated circuit attached to a substrate;
a lid over the photonic integrated circuit, wherein the lid directly contacts a top of the substrate such that the photonic integrated circuit is present in between the substrate and the lid;
optical waveguides attached to the photonic integrated circuit; and
a ferrule attached to the optical waveguides.

16. The optical module of claim 15, wherein the optical waveguides are selected from the group consisting of: polymer optical waveguides, glass optical waveguides, silicon optical waveguides, and combinations thereof.

17. The optical module of claim 15, further comprising:
a socket attached to the lid above the photonic integrated circuit, wherein the ferrule is plugged into the socket.

18. An optical module, comprising:
a lid;
a photonic integrated circuit disposed on the lid;
a substrate over and attached to the photonic integrated circuit, wherein the lid directly contacts a bottom of the substrate such that the photonic integrated circuit is present in between the substrate and the lid;
optical waveguides attached to the photonic integrated circuit; and
a ferrule attached to the optical waveguides.

19. The optical module of claim 18, wherein the optical waveguides are selected from the group consisting of: polymer optical waveguides, glass optical waveguides, silicon optical waveguides, and combinations thereof.

20. The optical module of claim 18, further comprising:
a cut-out in the substrate over the photonic integrated circuit.
